(19) United States
(12) Patent Application Publication
(10) Pub. No.: US 2026/0096071 A1
(43) Pub. Date: Apr. 2, 2026

(54) POWER SUPPLY MODULE AND VAPOR CHAMBER

(71) Applicant: MetaPWR Electronics Co., Ltd., Shanghai (CN)

(72) Inventors: Qingdong CHEN, Shanghai (CN); Hongxiu LIU, Shanghai (CN); Shouyu HONG, Shanghai (CN); Shengli Lu, Shanghai (CN)

(73) Assignee: MetaPWR Electronics Co., Ltd., Shanghai (CN)

(21) Appl. No.: 19/340,875

(22) Filed: Sep. 26, 2025

(30) Foreign Application Priority Data
Jun. 23, 2025 (CN) 202510844639.6
Sep. 28, 2024 (CN) 202411364225.5

(51) Int. Cl. H05K 7/20

(52) U.S. Cl. CPC H05K 7/209

(57) ABSTRACT

The present application discloses a power supply module having high thermal conductivity and high reliability, and a vapor chamber, comprising a substrate, a thermally conductive material and a vapor chamber, wherein a thermally conductive material is provided between the vapor chamber and the substrate; the vapor chamber comprises a vapor chamber primary side region, a vapor chamber secondary side region, and a connecting region, the vapor chamber primary side region is disposed above the primary side portion of the substrate, the vapor chamber secondary side region is disposed above the secondary side portion of the substrate, and the vapor chamber primary side region and the vapor chamber secondary side region form an integral structure by means of the connecting region.

### CROSS-REFERENCE TO RELATED APPLICATIONS

This application claims the priority benefit of Chinese patent application CN 202411364225.5 filed on Sep. 28, 2024 and Chinese patent application CN 202510844639.6 filed on Jun. 23, 2025. The entirety of the above-mentioned patent application is hereby incorporated by reference herein and made a part of this specification.

### BACKGROUND

### Technical Field

The present disclosure relates to the technical field of power supply module, and in particular to power supply module and vapor chamber.

### Description of Related Art

At present, there are two heat dissipation structures used in a high-voltage power supply module:

Heat sinks for a primary side of a substrate and a secondary side of the substrate, are separately designed, and then assembled with the primary side of the substrate and the secondary side of the substrate, respectively; the primary heat sink is bonded to the primary side device of the substrate by means of the adhesive glue to form a whole; the secondary heat sink of is assembled with the screw hole of the substrate by means of a screw; however, this method is applicable to a limited range, and the main reason is that the module can only use wave soldering at the customer and cannot be suitable for reflow soldering. Because the primary heat sink of the substrate is bonded to the primary side device through the adhesive, when the primary side device refuses during the reflow soldering process, the thermal expansion of the heat sink pulls apart the primary side device, causing the solder joint to open.

In another approach, a whole vapor chamber is provided above the substrate, and is locked with a screw hole of the substrate by means of a screw. In this way, at least two layers of Mylar piece need to be attached to the contact portion between the primary side of the substrate and the vapor chamber. In addition, in order to ensure that the corner position is completely covered, the vapor chamber needs to be epitaxial, so that the corner of the vapor chamber directly avoids the primary side device, thereby meeting the safety requirements of the primary and secondary side of the substrate with the vapor chamber, but this will inevitably lead to the size of the vapor chamber being greater than the size of the substrate, causing the waste of the space of the client board. Furthermore, since the thermal conductivity of the Mylar piece is very poor, the thermal resistance of the interface between the primary device and the vapor chamber becomes larger, and the heat dissipation is poor. In addition, in order to meet the safety requirements of the primary device and the vapor chamber, the bonding between the Mylar piece and the vapor chamber needs to be very tight, and the distance between each layer of the Mylar piece is to satisfy the safety rule distance, which makes the vapor chamber above the primary device as a flat surface as much as possible, so that the Mylar piece is better attached; If there is a step in the vapor chamber, it is difficult to coat the Mylar piece at the step position, and it is difficult to satisfy the safety rule distance. In order to meet the safety requirements of the vapor chamber and the substrate, there is no support point at the primary side of the substrate, and when the vapor chamber is stressed, the vapor chamber is easily deformed.

To sum up, the high-voltage power supply module needs to realize the following four functions:

(1) the power supply module needs to process reflow soldering and wave soldering simultaneously;

(2) reducing the thermal resistance from the primary side device to the housing;

(3) the vapor chamber has strong bending resistance;

(4) The size of the vapor chamber is equivalent to the size of the substrate, thereby saving the space of the client board.

### SUMMARY

In view of the above, one of the objectives of the application is to provide a power supply module, comprising a substrate, a thermally conductive material and a vapor chamber, wherein the substrate comprises a primary side portion and a secondary side portion, the primary side portion is provided with a primary side device, the secondary side portion is provided with a secondary side device, the vapor chamber is disposed on the substrate, and a thermally conductive material is provided between the vapor chamber and the substrate.

The vapor chamber includes a vapor chamber primary side region, a vapor chamber secondary side region, and a connecting region. The vapor chamber primary side region is disposed above the primary side portion, the vapor chamber secondary side region is disposed above the secondary side portion, and the vapor chamber primary side region and the vapor chamber secondary side region form an integral structure through the connecting region.

Preferably, the connecting region is a first insulating member, and the vapor chamber primary side region and the vapor chamber secondary side region are thermally conductive components; and a primary side portion and a secondary side portion of the substrate are electrically isolated; the vapor chamber primary side region and the vapor chamber secondary side region are thermally conductive member.

Preferably, the vapor chamber primary side region is provided with a boss structure, and the boss structure is used for realizing the support between the vapor chamber and the substrate.

Preferably, further comprising a heat sink, a ceramic plate being disposed between the heat sink and the vapor chamber, the ceramic plate and the vapor chamber are fixed by a thermally conductive adhesive; a thermally conductive material is disposed between the ceramic plate and the heat sink.

Preferably, the thermally conductive material comprises a thermally conductive gel, a thermally conductive silicone grease or a thermally conductive gasket.

A vapor chamber comprises a vapor chamber primary side region, a vapor chamber secondary side region, and a connecting region, the vapor chamber primary side region is disposed above a primary side portion of a substrate, the vapor chamber secondary side region is disposed above a secondary side portion of the substrate, and the vapor chamber primary side region and the vapor chamber secondary side region form an integral structure by means of a connecting region; The primary side portion and the secondary side portion of the substrate are electrically isolated.

Preferably, the connecting region is a first insulating member; the vapor chamber primary side region and the vapor chamber secondary side region are thermally conductive members.

Preferably, the vapor chamber primary side region is provided with a boss structure, and the boss structure is used for realizing the support between the vapor chamber and the substrate.

Preferably, the upper surface of the vapor chamber is attached to a first Mylar piece and a second Mylar piece, the first Mylar piece and the second Mylar piece both have a bent portion, the bent portion extends from the side edge of the vapor chamber to the lower surface of the vapor chamber, and the first Mylar piece and the second Mylar piece are attached to the vapor chamber primary side region.

Preferably, a second insulating member and a third insulating member are respectively provided at two corners on the outer side of the vapor chamber primary side region.

Preferably, the vapor chamber primary side region is provided with a first support region, a second support region and a third support region; the first support region is adapted to the first insulating member, the second support region is adapted to the second insulating member, and the third support region is adapted to the third insulating member.

Preferably, the first support region, the second support region, and the third support region are respectively provided with positioning pins, the first insulating member, the second insulating member, and the third insulating member are respectively provided with pin holes, and the positioning pins are adapted to the pin holes.

Preferably, a side wall of the first insulating member is provided with a recess structure.

Preferably, the vapor chamber primary side region and the vapor chamber secondary side region are respectively provided with heat dissipation fins.

Preferably, the vapor chamber primary side region comprises a non-metallic insulating material having good thermal conductivity, the vapor chamber primary side region comprises a primary side overlapping area, the vapor chamber secondary side region comprises a secondary side overlapping area, and the primary side overlapping area and the secondary side overlapping area are overlapped.

Preferably, the secondary side overlapping area is disposed above the primary overlapping area, and the primary overlapping area is disposed above the primary side device.

Preferably, a buffer material is provided between the vapor chamber primary side region and the vapor chamber secondary side overlapping area.

Preferably, a fastening hole is provided on both the vapor chamber secondary side overlapping area and the vapor chamber primary side overlapping area, and the fastener is securely connected to the fastening hole through the substrate.

Preferably, the upper surface and/or the lower surface of the substrate is provided with an insulating material close to the periphery of the fastener.

Preferably, the vapor chamber primary side region is bonded to the substrate through a bonding material, and the vapor chamber secondary side region is fixed independently of the substrate.

Compared with the prior art, the application has the following beneficial effects:

(1) The power supply module of the present application divides the vapor chamber into a vapor chamber primary region and a vapor chamber secondary region, the vapor chamber primary region is attached to the primary side of the substrate and/or devices, and the secondary side region of the vapor chamber is attached to the secondary side of the substrate and/or devices, such that the problem of safety rules is solved without additionally providing a Mylar piece between the vapor chamber and the primary side device, such that the thermal resistance between the primary side device of and the primary side region of the vapor chamber only has the thermal resistance of the thermally conductive material, thereby greatly reducing the thermal resistance from the heat generating device to the vapor chamber. According to the structure of the present application, since the Mylar piece is eliminated in the effective heat dissipation region, the heat dissipation risk of the product is reduced, and the service life of the product is greatly improved.

(2) Since there is no need to consider the problem of safety rules between the primary region of the vapor chamber and the primary device of the substrate, a boss can be provided at any position in the primary region of the vapor chamber to support the substrate, thereby achieving better support between the vapor chamber and the substrate, and avoiding deformation of the vapor chamber.

(3) Since the primary side device and the secondary side device each have a corresponding vapor chamber, the size of the vapor chamber can be equivalent to the size of the substrate.

### BRIEF DESCRIPTION OF THE DRAWINGS

FIG. 1 is a schematic structural diagram of a power supply module disclosed in an embodiment of the present application.

FIG. 2 is a schematic structural diagram of a boss structure according to an embodiment of the present disclosure.

FIG. 3 is a schematic structural diagram of a power supply module disclosed in another embodiment of the present application.

FIG. 4 is a schematic structural diagram of a vapor chamber disclosed in an embodiment of the present application.

FIG. 5 is a schematic structural diagram of an interference assembly structure of a vapor chamber disclosed in an embodiment of the present application.

FIG. 6 is a schematic structural diagram of a power supply module disclosed in another embodiment of the present application.

FIG. 7 is a schematic structural diagram of a power supply module disclosed in another embodiment of the present application.

FIG. 8 is a schematic structural diagram of a power supply module disclosed in another embodiment of the present application.

FIG. 9 is a schematic structural diagram of a power supply module disclosed in another embodiment of the present application.

FIG. 10 is a schematic diagram of creepage at a primary-side fastener of a high-heat-conductivity and high-reliability power supply module disclosed in an embodiment of the present application.

FIG. 11 is a schematic structural creepage path diagram of a power supply module disclosed in another embodiment of the present application.

FIG. 12 is a schematic structural diagram of a power supply module disclosed in another embodiment of the present disclosure.

### DESCRIPTION OF THE EMBODIMENTS

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

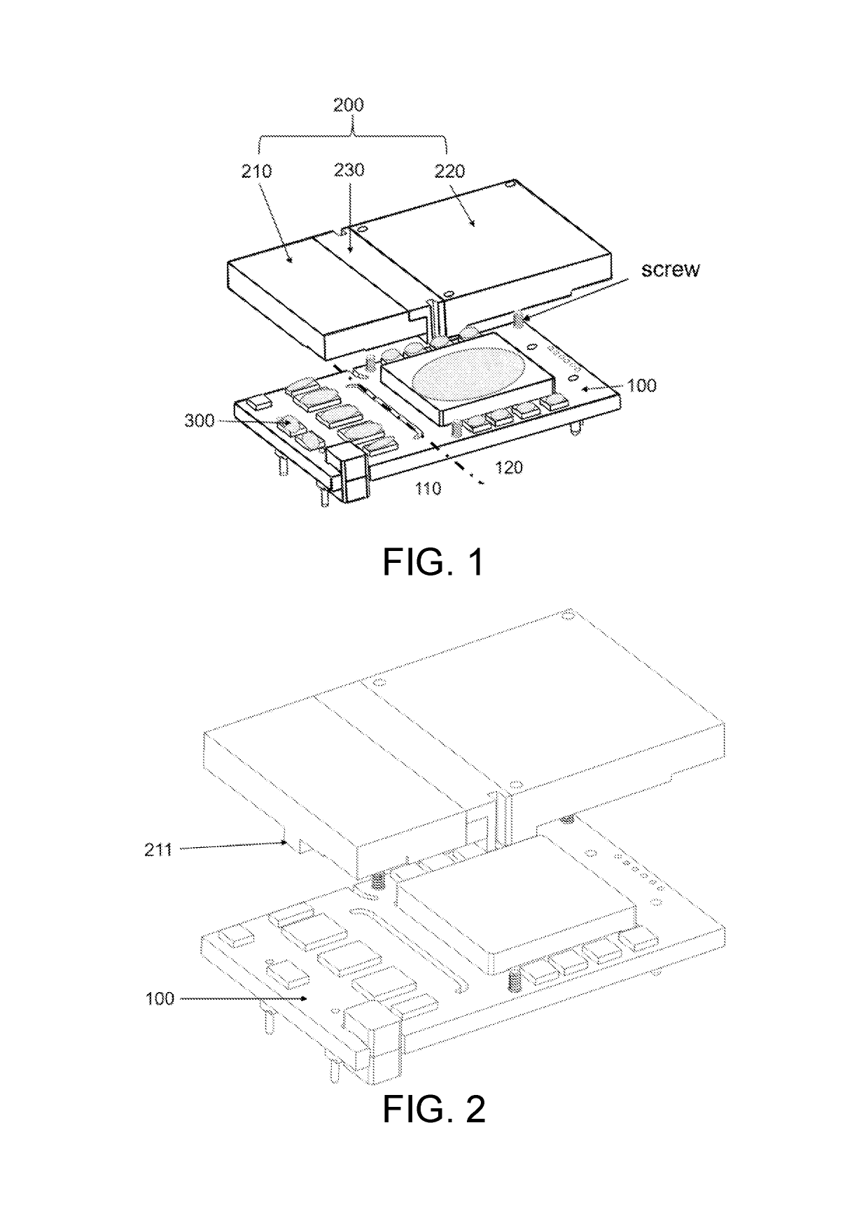

FIG. 1 shows a high-conductivity and high-reliability power supply module disclosed in an embodiment of the present application, comprising a substrate 100, a thermally conductive material 300 and a vapor chamber 200, wherein the substrate 100 comprises a primary side portion 110 and a secondary side portion 120, the primary side portion 110 is provided with a primary side device, the secondary side portion 120 is provided with a secondary side device, and the primary side portion 110 and the secondary side portion 120 are electrically isolated; The vapor chamber 200 is provided on the substrate 100, and a thermally conductive material 300 is provided between the vapor chamber 200 and the substrate 100. The thermally conductive material 300 comprises, but is not limited to, a thermally conductive gel and thermally conductive silicone grease. Since the hardness of the thermally conductive material is very low, the open-circuit or short-circuit problem of the devices is not caused during the reflow soldering process, and therefore, the requirements of reflow soldering and wave soldering can be satisfied simultaneously.

The vapor chamber 200 is of an assembled structure. The vapor chamber 200 comprises a vapor chamber primary side region 210, a vapor chamber secondary side region 220, and a connecting region 230. The vapor chamber primary side region 210 is disposed above the primary side portion 110, the vapor chamber secondary side region 220 is disposed above the secondary side portion 120, and the vapor chamber primary side region 210 and the vapor chamber secondary side region 220 form an integral structure by means of the connecting region 230. Preferably, the vapor chamber primary side region 210 and the vapor chamber secondary side region 220 are generally metal plates having a heat conduction function, and the connecting region 230 is a first insulating member.

In the embodiments of the present application, the vapor chamber 200 is divided into a vapor chamber primary side region 210 and a vapor chamber secondary side region 220, the vapor chamber primary side region 210 is attached to the primary side portion 110, and the vapor chamber secondary side region 220 is attached to the secondary side portion 120, so that there is no need to additionally provide a Mylar piece between the vapor chamber 200 and the primary side device to solve the problem of safety rules, such that the thermal resistance between the primary side device and the vapor chamber primary side region 210 is only a thermal resistance of the thermally conductive material, and the thermal conductivity of the thermally conductive material can generally be 3 W/(m.K) or more, and may even achieve 10 W/(m.K). In the prior art, a Mylar piece is disposed between a primary side device and a vapor chamber 200 to solve the problem of insulation and safety rules, and a thermally conductive material is provided between the Mylar piece and the primary side device. In general, at least two layers of the Mylar piece have a thickness of 0.1 mm, and the thermal conductivity is substantially between 0.1-0.3 W/(m.K). By means of the formula R = t /(λ A) of the thermal resistance, wherein R-thermal resistance, t-thickness, λ-thermal conductivity, and A-area. It is not difficult to see that in the case of a certain thickness, the thermal resistance achievable by the present application is 10% -30% of the existing thermal resistance, and the thermal resistance from the heat-source device to the vapor chamber 200 is greatly reduced. During long-term use, the bonding strength of the Mylar piece gradually decreases, and in severe cases, the Mylar piece is directly peeled off from the vapor chamber 200, and the heat dissipation performance is greatly reduced. According to the structure of the present application, since the Mylar piece is eliminated in the effective heat dissipation region, the heat dissipation risk of the product is reduced, and the service life of the product is greatly improved.

As shown in FIG. 2, since there is no need to consider a safety rule problem between the vapor chamber primary side region 210 and the primary side device, the boss structure 211 can be provided at any position of the vapor chamber primary side region 210 to support the substrate 100, thereby achieving better support between the vapor chamber 200 and the substrate 100, and avoiding deformation of the vapor chamber 200.

Since the primary side device and the secondary side device adhere to the corresponding vapor chamber regions, the size of the vapor chamber 200 can be equivalent to the size of the substrate 100.

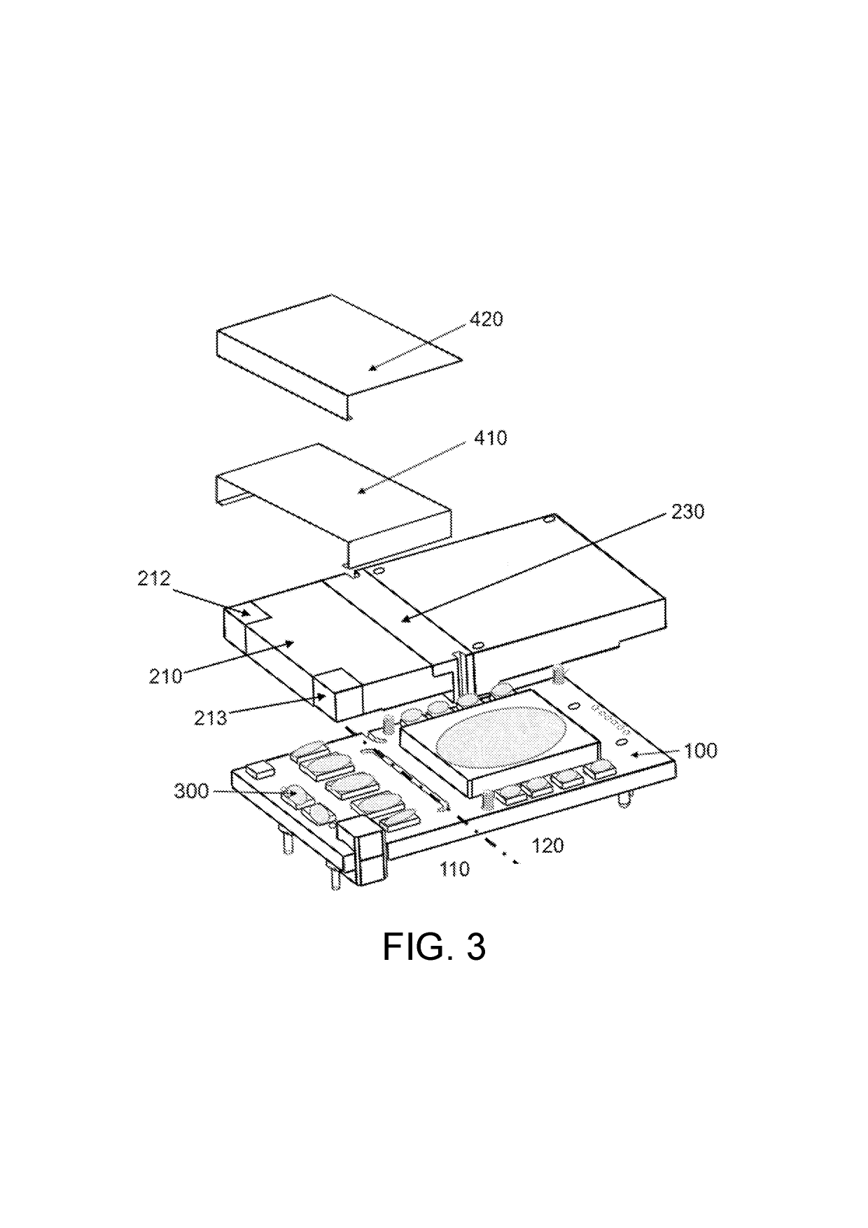

As shown in FIG. 3, considering a system application of the power supply module, a second insulating member 212 and a third insulating member 213 are respectively provided at two corners on the outer side of the vapor chamber primary side region 210, and the upper surface of the vapor chamber 200 is attached to the first Mylar piece 410 and the second Mylar piece 420, and the bent portion of the Mylar piece extends from the side edge to the lower surface of the vapor chamber 200, so as to meet the safety requirements, and the thickness of the second insulating member 212 and the third insulating member 213 are generally set to 4-8 mm.

A Mylar piece is disposed above the vapor chamber primary side region 210. Compared with the prior art in which a Mylar piece is disposed between the vapor chamber 200 and the heat-source device, the thermal resistance is still to be optimized. Specifically, the heat-source device transfers heat to the vapor chamber 200 by means of the thermally conductive material, and to achieve temperature uniformity through the vapor chamber 200, such that the area of upward heat transfer is expanded to the area of the whole vapor chamber primary side area 210, and then passes through the first Mylar piece 410 and the second Mylar piece 420 and then transfers to the heat sink of the customer. According to the above thermal resistance calculation formula, the heat conduction area A increases, and the thermal resistance will still be significantly reduced.

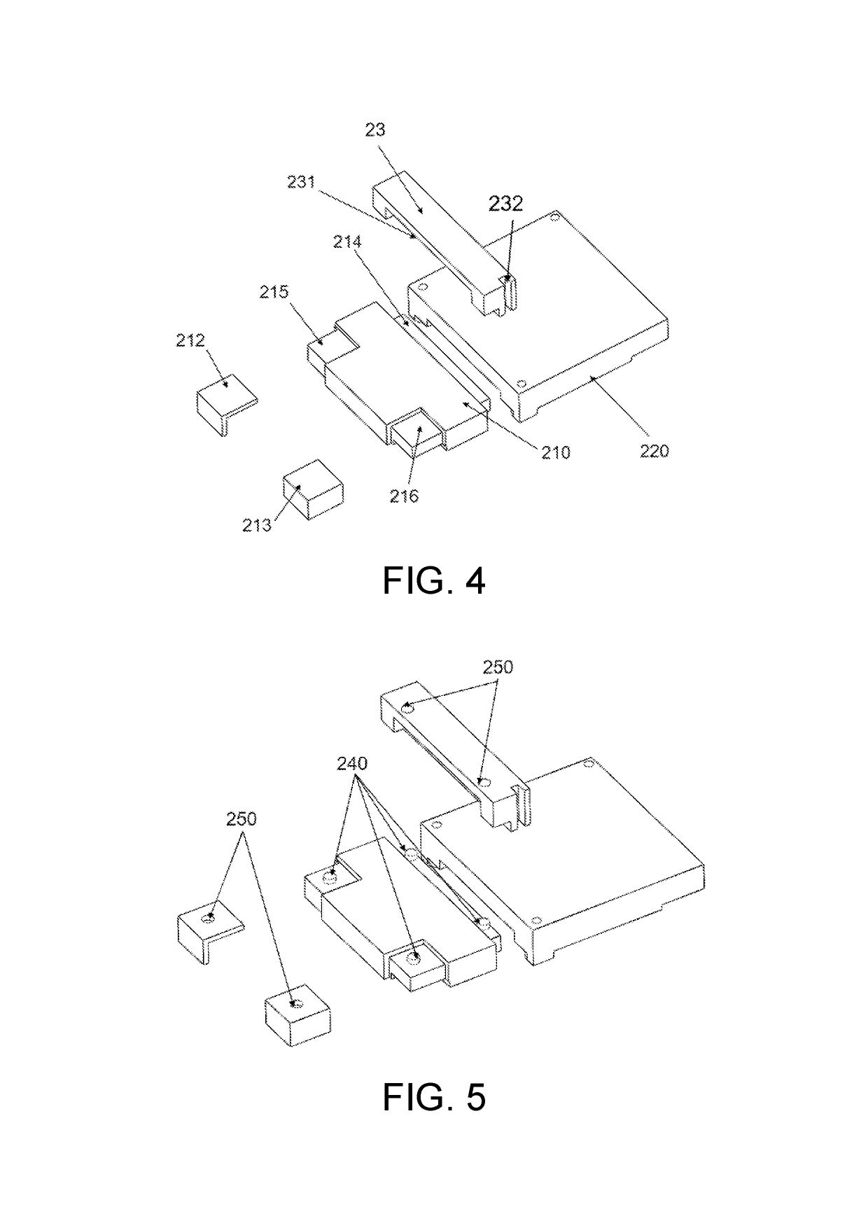

As shown in FIG. 4, the vapor chamber primary side region 210 is provided with a first support region 214, a second support region 215 and a third support region 216. The second support region 215 is adapted to the second insulating member 212, the third support region 216 is adapted to the third insulating member 213, the side wall of the first insulating member 230 is provided with a recess structure 231 and 232, the first support region 214 is adapted to the recess structure 231, the recess structure 231 and the recess structure 232 are used for increasing the creepage distance between the vapor chamber primary side region 210 and the vapor chamber secondary side region 220, and the connection method is not limited to bonding and welding.

As shown in FIG. 4, in order to improve the connection strength, the first support region 214, the second support region 215, and the third support region 216 of the vapor chamber primary side region 210 are respectively provided with a positioning pin 240, the first insulating member 23, the second insulating member 212 and the third insulating member 213 are respectively provided with pin holes 250, and the positioning pins 240 are adapted to the pin holes 250, such that the first support region 214 and the first insulating member 23, the second support region 215 and the second insulating member 212, the third support region 216 and the third insulating member 213 form an interference assembly, thereby improving the connection strength. In addition, an adhesive glue can be provided between the insulating member and the support region, so as to further improve the strength of the vapor chamber 200, and the adhesive glue needs to meet the high-temperature resistance requirement, such as reflow soldering.

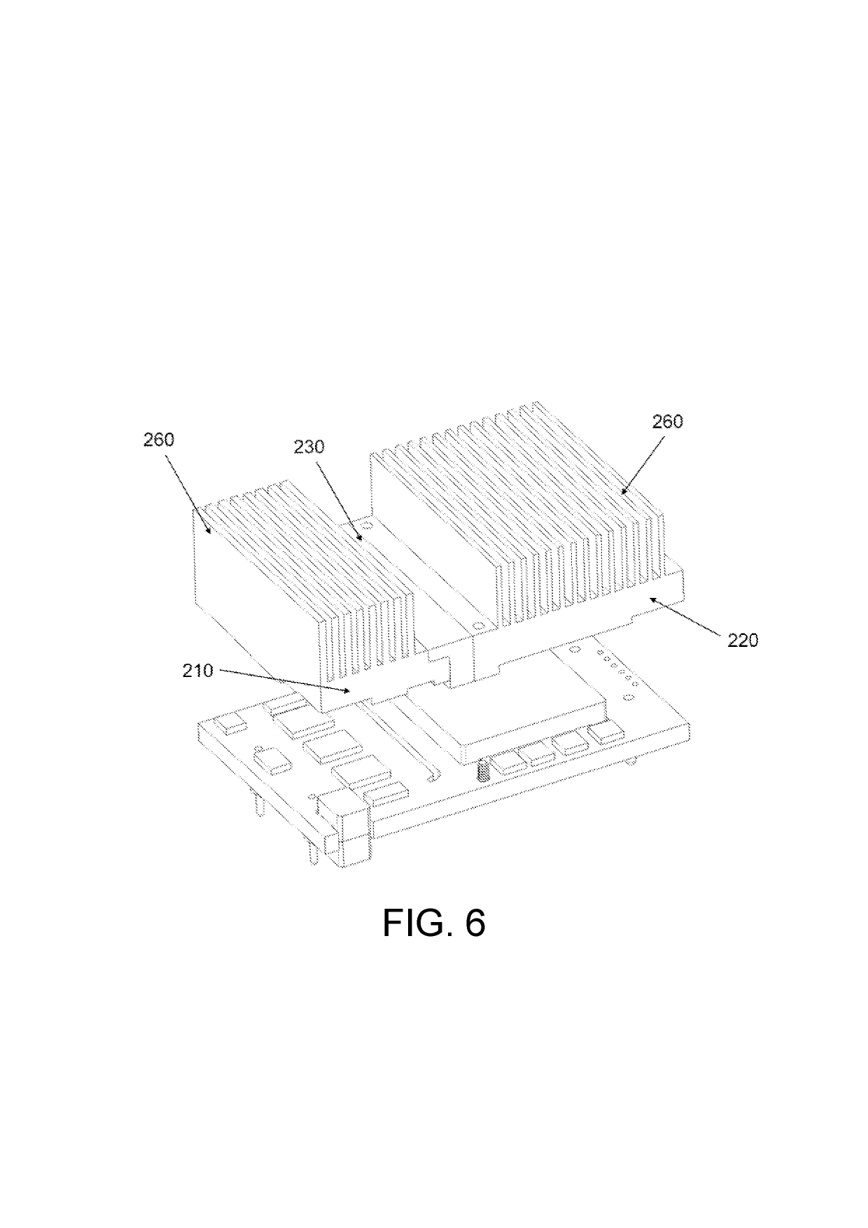

As shown in FIG. 6, in order to further reduce the thermal resistance between the vapor chamber 200 and the client HSK, the vapor chamber primary side region 210 further comprises a fin structure 260 for dissipating heat to the primary side device, and the vapor chamber secondary side region 220 further comprises a fin structure 260 for dissipating heat from the secondary side device. In the present embodiment, the thermal resistance of the Mylar piece are reduced, and heat dissipation performance is improved. The vapor chamber primary side region 210 of the present embodiment is bound to the vapor chamber secondary side region 220 by means of the connecting region 230, and then is interlocked with the substrate 100 by means of the screw holes of the vapor chamber secondary side region 220, so that the vapor chamber primary side region 210 does not need to be bonded to the substrate 100 or the device on the substrate 100, and can still ensure that there is sufficient strength to deal with external vibration and impact.

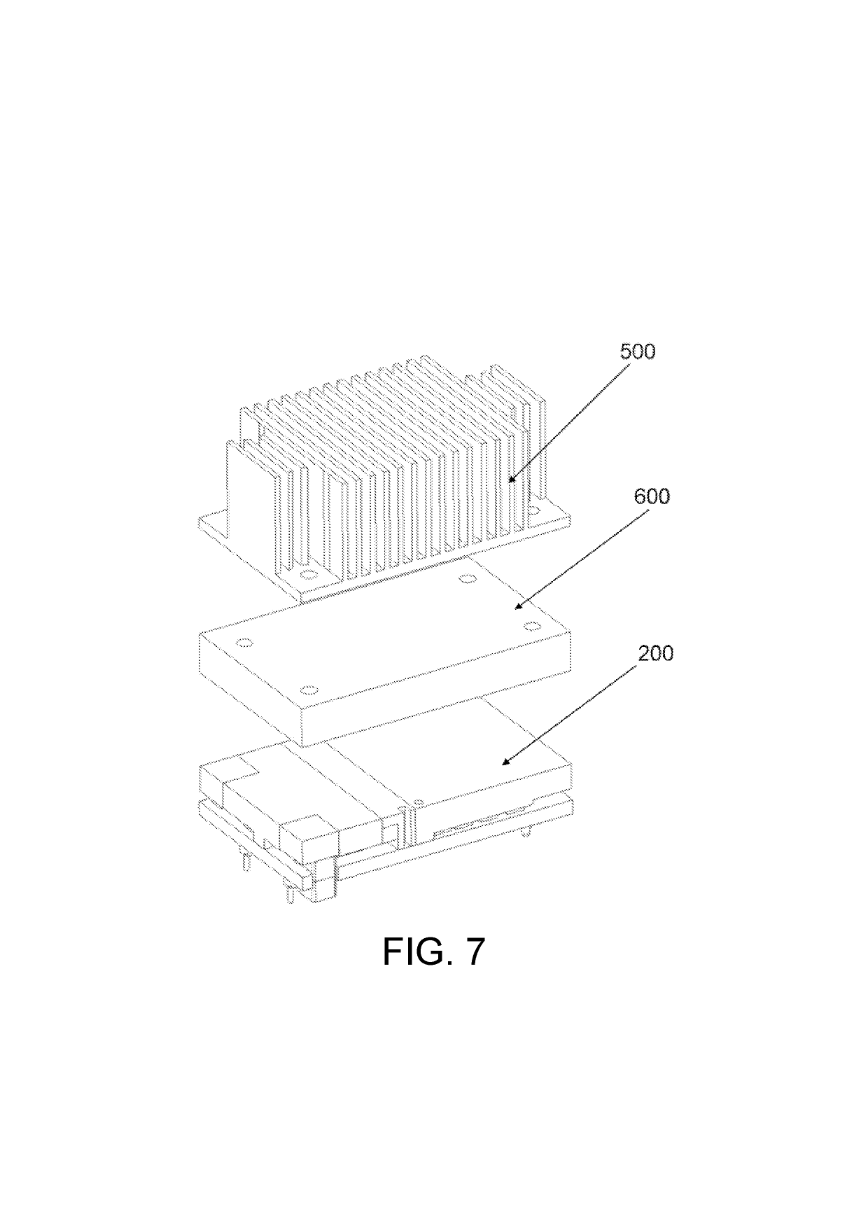

In some application scenarios, the heat sink 500, the vapor chamber primary side region 210 and the vapor chamber secondary side region 220 do not have the same potential, so as to meet the safety rule insulation requirements, furthermore to ensure that a sufficient safe distance between the heat sink 500 and the vapor chamber primary side region 210, and between the heat sink 500 and the vapor chamber secondary side region 220. As shown in FIG. 7, a ceramic plate 600 is provided between the heat sink 500 and the vapor chamber 200 to achieve a safety rule insulation requirement between the heat sink 500 and the vapor chamber 200. The heat sink 500 is locked to the ceramic plate 600 by means of a screw. The threads on the ceramic plate 600 are realized by means of an embedded metal nut. The four holes of the ceramic plate 600 are all depth-controlled holes, so as to satisfy the safety rule insulation requirements between the screw and the vapor chamber 200. Specifically, the ceramic plate 600 and the vapor chamber 200 are fixed to form a whole by means of a thermally conductive adhesive glue; a thermally conductive material, such as a thermally conductive adhesive, a thermally conductive silicone grease, a thermally conductive pad, etc. is provided between the ceramic plate 600 and the heat sink 500, and is not limited thereto.

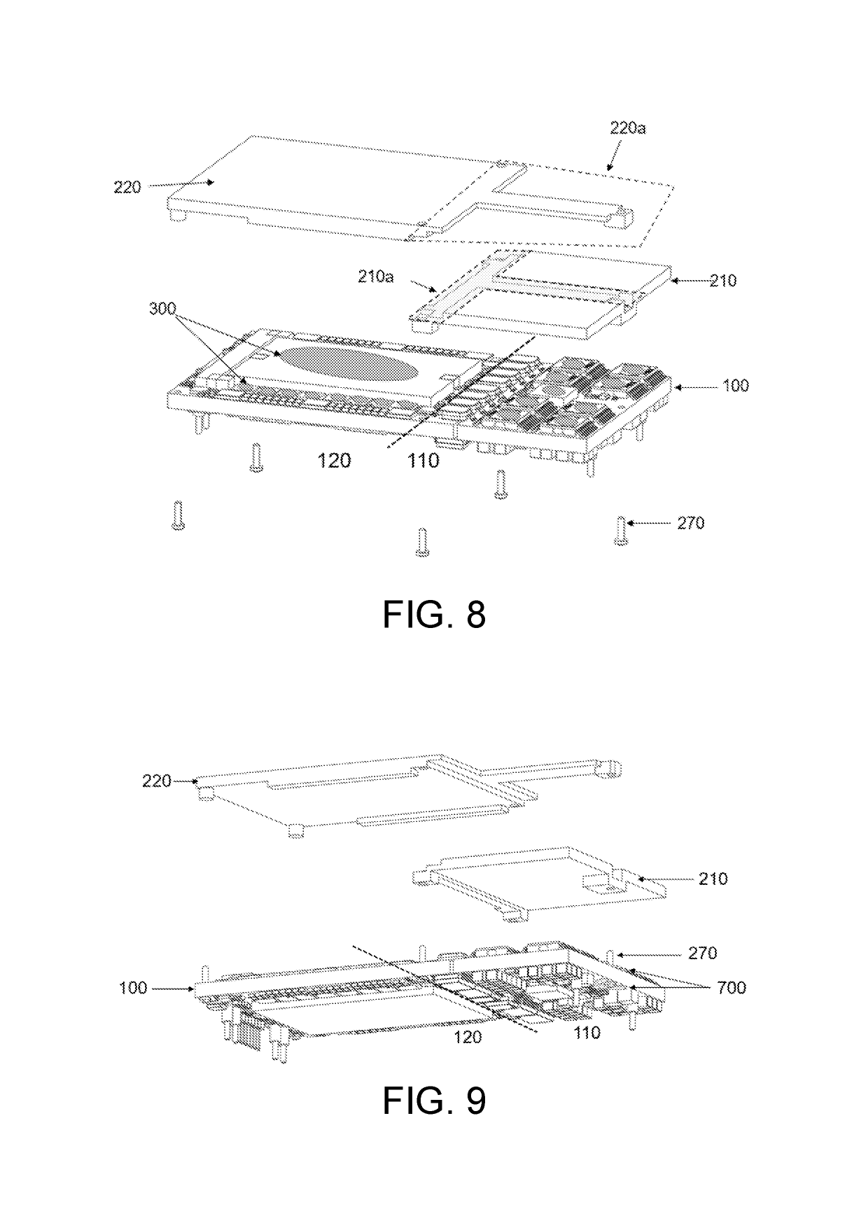

As shown in FIG. 8, in order to achieve better heat dissipation and safety performance, the vapor chamber primary side region 210 uses a non-metal insulating material having good thermal conductivity. an overlapping area exists between the vapor chamber primary side region 210 and the vapor chamber secondary side region 220 during assembly, the vapor chamber primary side region 210 comprises a primary side overlapping area 210a, and the vapor chamber secondary side region 220 comprises a secondary side overlapping area 220a; that is, the secondary side overlapping area 220a may extend above the primary side device. The primary side overlapping area 210a and the secondary side overlapping area 220a are overlapped, and a vapor chamber primary side region 210 is provided between the primary side device and the secondary side overlapping area 220a, so as to satisfy the safety insulation requirement of the primary and secondary side. A threaded hole is provided on the vapor chamber secondary side region 220, and overlaps with the vapor chamber primary side region 210 at the screw hole position, and the fastener 270 can be fastened to the threaded hole in the vapor chamber secondary side region 220 through the substrate 100 and the vapor chamber primary side region 210. Since the vapor chamber primary side region 210 is a non-metal insulating material having good thermal conductivity, such as ceramic, the product can be well dissipated in the application to meet the safety insulation requirements of the product at the same time.

In order to avoid cracking of the non-metal insulating material during the fastening process, a buffer material (not shown) may be added in the overlapping area of the vapor chamber primary side region 210 and the vapor chamber secondary side region 220 ).

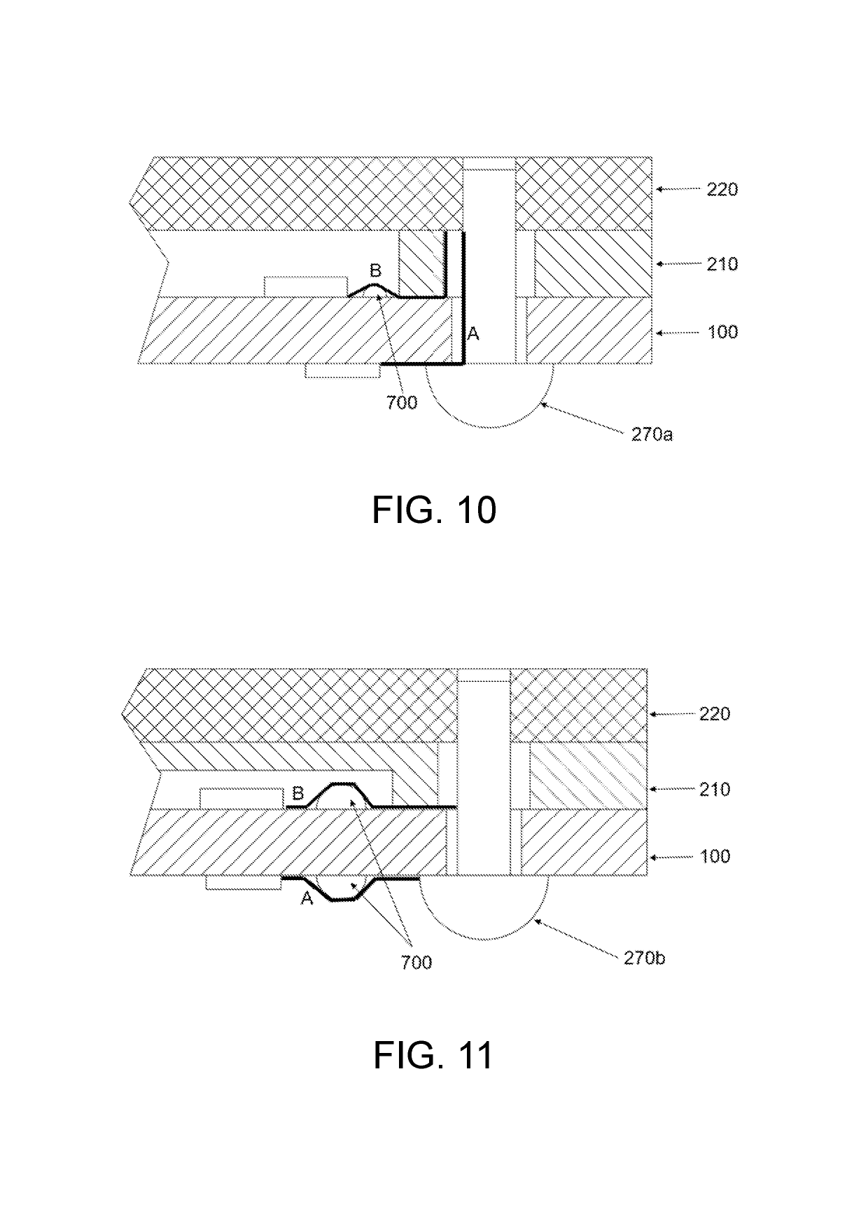

On the basis of the previous embodiment, further, for higher power density and integration level, more devices or lines are often required to be arranged in a smaller space. In addition, the periphery of the metal material fastener of the primary side portion 110 is a requirement for satisfying the safety creepage distance, and a large area around the mounting hole is prohibited from being provided with a circuit and a component, which has a large space waste. According to the present embodiment, on the basis of the previous embodiment, a circle of insulating material 700 is arranged on the periphery of the fastener 270 in the primary side portion 110, as shown in FIG. 9, the fastener 270 is a metal fastener, and the minimum creepage path of the device or line of the primary side portion 110 needs to be flipped over the insulating material 700, thereby greatly increasing the creepage distance, and the creepage path is shown in FIG. 10, thereby increasing the product power density and integration level while also increasing the safety of the product. The insulating material 700 can be an insulating material such as a curing adhesive and a plastic.

In some low-mechanical-strength application scenarios, in order to better achieve the application effect of the previous embodiment, the fastener may be replaced with a fastener 270a made of an insulating material, such as a ceramic screw or a plastic screw. It should be noted that even if a non-metallic material fastener is used, the distance between the primary side device or the line with the mounting hole is still at risk that does not meet the requirements of the safety creep distance. In this embodiment, the non-metallic fastener 270a may be used alone, or in order to further save space, the non-metallic fastener 270a and the insulating material 700 are used in combination to achieve a better effect. As shown in FIG. 11, the creepage distance A of the device on the substrate 100 close to the non-metal fastener 270a satisfies the safety requirement, but the creepage distance B of the substrate 100 away from the non-metal fastener 270a does not meet the safety requirements, and the insulation material 700 is added to the periphery of the screw hole on which the safety requirements are not met, so that the creepage distance B path is increased because of bending, thereby satisfying the requirements of safety and voltage creepage distance. Similarly, it is possible to determine whether there is a need to increase the use of the insulating material 700 while using the insulating material fastener according to specific requirements.

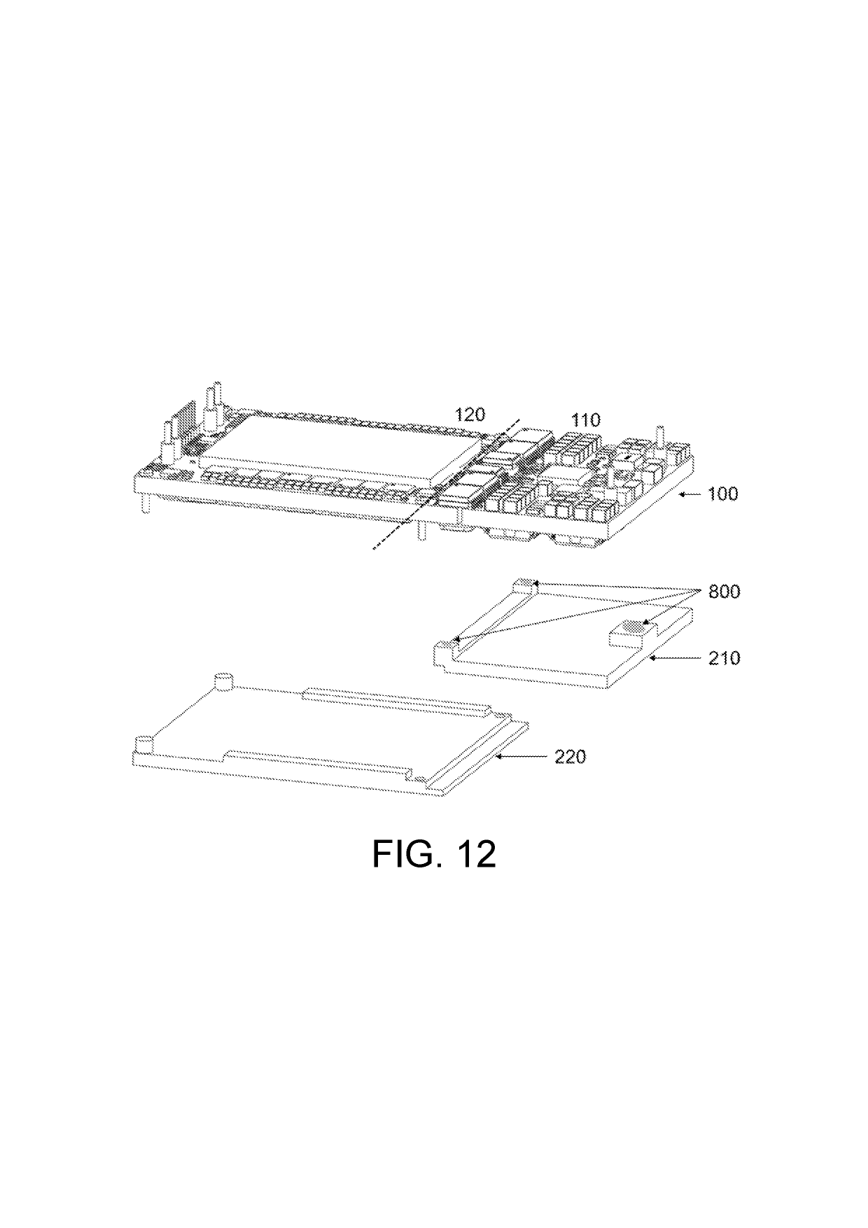

In order to further reduce the space waste caused by the safety distance, as shown in FIG. 12, in the present embodiment, an adhesive material 800 is used to replace the primary fastener 270, and the adhesive material 800 can be an epoxy resin or an organosilicon structural adhesive. During installation, the vapor chamber primary side region 210 is bonded to the substrate 100 by means of the adhesive material 800, and the vapor chamber secondary side region 220 is independently fixed to the substrate 100. In this application, the substrate 100 functions similar to the connecting region 230 in the above embodiments. Since the vapor chamber primary side region 210 is an insulating material, the creepage path caused by the mounting hole and the fastener in the above embodiments is blocked, the safety requirements of the product are greatly guaranteed, and the mounting hole cancellation can also provide more space for the electronic device and the circuit arrangement.

The embodiments in the present specification are described in a progressive manner, each embodiment focuses on the differences from other embodiments, and the same and similar parts between the various embodiments can be referred to each other.

The above description of the disclosed embodiments enables those skilled in the art to implement or use the present application. Various modifications to these embodiments will be readily apparent to those skilled in the art, and the general principles defined herein May be implemented in other embodiments without departing from the spirit or scope of the present application. Thus, the present application is not to be limited to the embodiments shown herein, but is to be accorded the widest scope consistent with the principles and novel features disclosed herein.

What is claimed is:

1. A power supply module, comprising a substrate, a thermally conductive material and a vapor chamber, wherein the substrate comprises a primary side portion and a secondary side portion, the primary side portion is provided with a primary side device, the secondary side portion is provided with a secondary side device, the vapor chamber is disposed on the substrate, and a thermally conductive material is provided between the vapor chamber and the substrate; and
the vapor chamber includes a vapor chamber primary side region, a vapor chamber secondary side region, and a connecting region, the vapor chamber primary side region is disposed above the primary side portion, the vapor chamber secondary side region is disposed above the secondary side portion, and the vapor chamber primary side region and the vapor chamber secondary side region form an integral structure through the connecting region.

2. The power supply module of claim 1, wherein the connecting region is a first insulating member, and the vapor chamber primary side region and the vapor chamber secondary side region are thermally conductive components; and a primary side portion and a secondary side portion of the substrate are electrically isolated; the vapor chamber primary side region and the vapor chamber secondary side region are thermally conductive member.

3. The power supply module of claim 1, wherein the vapor chamber primary side region is provided with a boss structure, and the boss structure is used for realizing the support between the vapor chamber and the substrate.

4. The power supply module of claim 1, further comprising a heat sink, a ceramic plate being disposed between the heat sink and the vapor chamber, the ceramic plate and the vapor chamber are fixed by a thermally conductive adhesive; a thermally conductive material is disposed between the ceramic plate and the heat sink.

5. The power supply module of claim 4, wherein the thermally conductive material comprises a thermally conductive gel, a thermally conductive silicone grease or a thermally conductive gasket.

6. A vapor chamber, comprising a vapor chamber primary side region, a vapor chamber secondary side region, and a connecting region, the vapor chamber primary side region is disposed above a primary side portion of a substrate, the vapor chamber secondary side region is disposed above a secondary side portion of the substrate, and the vapor chamber primary side region and the vapor chamber secondary side region form an integral structure by means of a connecting region; The primary side portion and the secondary side portion of the substrate are electrically isolated.

7. The vapor chamber of claim 6, wherein the connecting region is a first insulating member; the vapor chamber primary side region and the vapor chamber secondary side region are thermally conductive members.

8. The vapor chamber of claim 6, wherein the vapor chamber primary side region is provided with a boss structure, and the boss structure is used for realizing the support between the vapor chamber and the substrate.

9. The vapor chamber of claim 6, wherein the upper surface of the vapor chamber is attached to a first Mylar piece and a second Mylar piece, the first Mylar piece and the second Mylar piece both have a bent portion, the bent portion extends from the side edge of the vapor chamber to the lower surface of the vapor chamber, and the first Mylar piece and the second Mylar piece are attached to the vapor chamber primary side region.

10. The vapor chamber of claim 8, wherein a second insulating member and a third insulating member are respectively provided at two corners on the outer side of the vapor chamber primary side region.

11. The vapor chamber of claim 10, wherein the vapor chamber primary side region is provided with a first support region, a second support region and a third support region; the first support region is adapted to the first insulating member, the second support region is adapted to the second insulating member, and the third support region is adapted to the third insulating member.

12. The vapor chamber of claim 11, wherein the first support region, the second support region, and the third support region are respectively provided with positioning pins, the first insulating member, the second insulating member, and the third insulating member are respectively provided with pin holes, and the positioning pins are adapted to the pin holes.

13. The vapor chamber of claim 7, wherein a side wall of the first insulating member is provided with a recess structure.

14. The vapor chamber of claim 6, wherein the vapor chamber primary side region and the vapor chamber secondary side region are respectively provided with heat dissipation fins.

15. The vapor chamber of claim 6, wherein the vapor chamber primary side region comprises a non-metallic insulating material having good thermal conductivity, the vapor chamber primary side region comprises a primary side overlapping area, the vapor chamber secondary side region comprises a secondary side overlapping area, and the primary side overlapping area and the secondary side overlapping area are overlapped.

16. The vapor chamber of claim 15, wherein the secondary side overlapping area is disposed above the primary overlapping area, and the primary overlapping area is disposed above the primary side device.

17. The vapor chamber of claim 15, wherein a buffer material is provided between the vapor chamber primary side region and the vapor chamber secondary side overlapping area.

18. The vapor chamber of claim 15, wherein a fastening hole is provided on both the vapor chamber secondary side overlapping area and the vapor chamber primary side overlapping area, and the fastener is securely connected to the fastening hole through the substrate.

19. The vapor chamber of claim 18, wherein the upper surface and/or the lower surface of the substrate is provided with an insulating material close to the periphery of the fastener.

20. The vapor chamber of claim 6, wherein the vapor chamber primary side region is bonded to the substrate through a bonding material, and the vapor chamber secondary side region is fixed independently of the substrate.
